(19) United States
(12) Patent Application Publication
(10) Pub. No.: US 2014/0216539 A1
(43) Pub. Date: Aug. 7, 2014

(54) INTERDIGITATED ELECTRICAL CONTACTS FOR LOW ELECTRONIC MOBILITY SEMICONDUCTORS

(71) Applicants: Danvers E. Johnston, Lakeland, FL (US); Jonathan E. Allen, Philadelphia, PA (US); Charles T. Black, New York, NY (US); Chang-Yong Nam, Coram, NY (US)

(72) Inventors: Danvers E. Johnston, Lakeland, FL (US); Jonathan E. Allen, Philadelphia, PA (US); Charles T. Black, New York, NY (US); Chang-Yong Nam, Coram, NY (US)

(73) Assignee: BROOKHAVEN SCIENCE ASSOCIATES, LLC, Upton, NY (US)

(21) Appl. No.: 14/114,398

(22) PCT Filed: Apr. 27, 2012
(86) PCT No.: PCT/US12/35595

§ 371 Date: Mar. 11, 2014

Related U.S. Application Data
(60) Provisional application No. 61/480,192, filed on Apr. 28, 2011.

(51) Int. Cl. H01L 31/0224

(52) U.S. Cl. CPC H01L 31/022425
USPC 136/256; 438/98

(57) ABSTRACT

Structures useful for forming contacts to materials having low charge carrier mobility are described. Methods for their formation and use are also described. These structures include interdigitated electrodes capable of making electrical contact to semiconducting materials having low electron and/or whole mobility. In particular, these structures are useful for organic semiconducting devices made with conducting polymers and small molecules. They are also useful for semiconducting devices made with nanocrystalline semiconductors.

### CROSS-REFERENCE TO A RELATED APPLICATION

This application claims the benefit under 35 U.S.C. 119(e) of U.S. Provisional Application No. 61/480,192 filed on Apr. 28, 2011, the content of which is incorporated herein in its entirety.

### STATEMENT OF GOVERNMENT RIGHTS

This invention was made with Government support under contract number DE-ACO2-98CH10886, awarded by the U.S. Department of Energy. The Government has certain rights in the invention.

### FIELD OF THE INVENTION

The present invention relates to an electrode structure useful in semiconductor devices. More particularly, the present invention relates to the design and manufacture of interdigitated electrical contacts for low electronic mobility semiconductors. The present invention also relates to the design and manufacture of interdigitated electrical contacts for low electronic mobility semiconductors having a large channel width in a small footprint with enhanced gate coupling strength and full depletion of the channel material.

### BACKGROUND

Traditional solar cell architectures sandwich a semiconductor active layer between two (bottom and top) metallic contacts. The sequential layered fabrication process is straightforward, yet it has several limitations, namely: (1) it introduces risk of damaging the semiconductor active layer during formation of the top electrode; (2) the architecture requires one transparent electrical contact to allow light to access the photoactive semiconductor layer; and (3) the architecture necessarily couples the length scales for light absorption and charge collection (both are equal to the semiconductor layer thickness). These limitations are particularly prevalent in solar cell devices based on either inorganic nanocrystals, or organic semiconductors. The primary reason being that such materials typically have low electronic mobility, limiting carrier diffusion lengths to tens of nanometers.

Traditional silicon solar cells, as well as those based on other “high performance” materials, e.g., III-V semiconductors, often employ grating electrodes on the device top surface, which are composed of non-transparent metal wires separated by a distance that allows light to access the device interior. Although, the backside electrical contacts still remain as a continuous metal layer, the grating or wire pitch can be large due to a diffusion length within the semiconductor that allow the carriers to travel far enough for efficient collection.

This approach is, however, less appealing for lower-performance materials, such as nanocrystals and organic semiconductors, because wire pitches must be sufficiently. small (˜100 nm). Although there are examples of high-resolution patterning methods, they are typically used for optical transparency of the conducting layer. (See, e.g., Kang, M. et al., Adv. Mater.; 20, 4408 (2008), which is incorporated herein by reference in its entirety.) In this case, the addition of a continuous layer of poly(3,4-ethylenedioxythiophene) poly(styrenesulfonate) conducting polymer (PEDOT-PSS) is necessary to electrically bridge the gratings or wires.

Interdigitating (or interlocking) the two electrodes on the backside of the device circumvents the need to use wire pitches, and this approach has been implemented in silicon and other high-mobility semiconductor solar cell designs (See, e.g., Smith, D. and Gee, J., 16^{th} European Photovoltaic Solar Energy Conference (Glasgow, United Kingdom, 2000) and Van Kerschaver, E. and Beaucarne, G., Progress in Photovoltaics: Research and Applications, 14(2), 107-123 (2005), each of which is incorporated herein by reference in its entirety). The challenge of realizing interdigitated electrode architectures in lower-mobility materials, such as organic semiconductor and nanocrystal materials, is in patterning electrode sizes and separations on sub-100-nm length scales in order to match charge carrier diffusion lengths, as well as patterning interdigitated electrodes of two different metals.

Moreover, many practical applications of lower-mobility materials are particularly constrained by the relatively large lateral area occupied by the devices for sufficient current output. For example, organic field effect transistors (FETs) are typically used in organic light emitting displays that have an array of pixels having both an organic light emitting diode (OLED) and the individual FETs, i.e., power electronics. The limited space available for each pixel is shared by both the OLED and the FET. The pixel aperture ratio, which is defined as the ratio of the physical area occupied by the OLED to the area occupied by its associated FET, is determined by the current density requirements of the OLED (typically >1 mA/cm²) and the area current density output of the FET. (Gu, G. et al. IEEE Journal of Selected Topics in Quantum Electronics, vol. 4, no. 1, pp. 83-99, February 1998, incorporated herein by reference). Higher aperture ratio is desirable because a larger percentage of display area can be dedicated to light production. Thus, it would be desirable to produce FETs that occupy smaller physical area, yet that have the same current density output.

The lower-mobility materials are also constrained by the small active region of the semiconductor film. Active region thickness is determined by dielectric (Debye) screening length. The Debye screening length (L_{D}) in the semiconductor under flat band conditions can be expressed as,

L_{D}=\sqrt{εₛε₀k_{B}T/e²n,}

where εₛ is the relative permittivity of the semiconductor, ε₀ the vacuum permittivity, k_{B} Boltzmann constant, T temperature, e elementary charge, and n charge carrier density. For instance, the Debye screening length (L_{D}) is a maximum in the organic field effect transistor off-state. Furthermore, the gate-controlled increase in the charge carrier density (n), that is the transition to the on-state, is accompanied by th.e reduction in the Debye screening length (L_{D}). The reduction in the Debye screening length (L_{D}) further shrinks the active region. With less than 100% of the semiconductor participating in device operation in the off-state, a parasitic channel exists, leading to a source of the drain leakage currents that can increase power consumption and reduce the device on/off ratio. A large portion of inactive semiconductor material is undesirable in the on-state for practical reasons such as the inefficient use of raw material, current leakage, and wasteful utilization of space in vertical device geometries.

Device architecture and, in particular, the electrode geometry can be engineered to promote a desired aspect of device performance, such as high power output. The conventional planar thin film geometry consists of source/drain electrodes separated by a channel of length L and buried under a film of organic semiconductor as illustrated in FIG. 1. The current output magnitude (I_{D}) is controlled by scaling the ratio of the channel width, W, to length, L, (W/L). Folding the channel by means of interdigitated electrodes, as shown in FIG. 3 (see Planar Interdigitated), is an example of a geometrical approach to increase the ratio W/L. In this way, low mobility polymeric semiconductors can provide high-current drive, for example for organic light emitting diode applications, by increasing channel width, W, decreasing channel length, L, or both. However, the strategy of increasing channel width, W, in a planar geometry increases device area in direct proportion to the channel width, W. On the other hand, reducing channel length, L, is feasible only within limits set by the gate oxide thickness (tₒₓ) and the resolution of the patterning method used to fabricate electrodes.

In contrast to a planar device, the transistor channel can be oriented vertically in the device architecture shown schematically in FIG. 2. This space-saving electrode geometry orients the semiconductor channel and the direction of current flow perpendicular to the plane of the semiconducting film. (Hergenrother, J. M. et al., Solid-State Electronics, vol. 46, no. 7, pp. 939-950, 2002; Ertosun, M. G. et al. IEEE Electron Device Letters, vol. 29, no. 6, pp. 615-617, 2008; both incorporated herein by reference in their entirety). Although, it has been suggested to improve the performance of these devices by utilizing a porous source electrode (McCarthy, M. A., et al. Nano Letters 10, 3467-3472, 2010) or micrometer-scale 3D vertical channels (Uno, M. et al. Appl. Phys. Lett. 97, 013301, 2010), these surface modifications rely on specific details of the materials at interfaces and is therefore not a universal approach to improving device performance.

Other active areas of research to improve performance of low-mobility devices is to synthesize novel organic semiconducting materials with improved charge transport properties and surface modification of dielectrics and electrodes. (Halik, M. et al. Nature 431, 963-966 (2004) and Germack, D. S. et al. Appl. Phys. Lett. 94, 233303 (2009); both incorporated herein by reference). While, the modification of surfaces can induce favorable molecular ordering within thin films of specific organic semiconductors, (Kline, J. R. et al. Nat Mater 5, 222-228 (2006) and Sirringhaus, H. et al. Nature 401, 685-688 (1999); both incorporated herein by reference), these modifications and substitutions are not well characterized and still have to prove their reliability, whereas the lower mobility semiconducting materials currently available are at a more advanced stage of manufacturing development for mass production.

Therefore, it would be desirable to provide a solution which overcomes the above-described inadequacies and shortcomings in the production of patterning electrode sizes and separations on <100 nm length scales in order to match charge carrier diffusion lengths in organic semiconductor and nanocrystal materials, as well as to pattern interdigitated electrodes of two different metals. Moreover, it would be desirable to produce devices with lower-mobility materials that provide high output power, yet have a small area footprint.

### SUMMARY

Recognizing the challenges of exploiting organic- and nanocrystal-based device architectures, in one embodiment, a method is provided that affords the production of interdigitated electrical contacts for low electronic mobility semiconductor devices at sub-one hundred-nanometer (<100 nm) length scale by forming the electrical contacts prior to deposition of the semiconductor active layer in a novel electrode structure architecture. Preferably, the method affords the production of metal contacts having one or more different materials with a large channel width in a small footprint, preferably with enhanced gate coupling strength and full depletion of the channel material.

In one embodiment, an electrode structure generally has (1) a bottom electrode; (2) a top electrode, and (3) an insulating column operable to insulate the bottom electrode from the top electrode. The top electrode is positioned on the top surface of the insulating column, whereas the bottom electrode is positioned on the substrate supporting the insulating column. The bottom electrode generally includes a continuous conducting layer positioned on the substrate that can extend under the insulating column. The insulating column can be positioned to be in contact with the substrate, while the bottom electrode does not extend between the insulating column and the substrate. The semiconducting material can be deposited between the insulating columns, preferably after the placement of the top and the bottom electrodes. Alternatively, the two interdigitated electrodes can be placed on the substrate and the semiconducting material is layered on top of the electrodes. The depth of either or both electrodes is preferably less than or equal to about 100 nanometers.

In another embodiment, an electrode structure has two (first and second) electrodes coplanar to each other that are supported on a common substrate. Preferably, the two interdigitated electrodes are placed on the substrate with the direction of the horizontal charge collection, e.g., photogenerated charge collection, orthogonal to the direction of the vertical absorption, e.g., light absorption. This provides for formation of thick active layers for light absorption while maintaining short charge collection lengths. The electrode structure also contains a semiconducting material. The electrodes can be made from different conducting materials and can be separated in the plane of the substrate by a predetermined linear distance. The inter-electrode spacing and height of either or both electrodes is set forth to depend on a characteristic charge carrier persistence length and the light absorption properties of the semiconducting material. Preferably, the width and spacing of either or both electrodes is less than about 100 nanometers. More preferably, the height of the electrodes is approximately equal to the predetermined absorption distance in the semiconductor. Thus, the electrode structure has vertically interdigitated electrodes with spacing that is smaller or equal to twice the charge screening length of the semiconducting material, which can be expressed as,

d≦2L_{D} (1),

where L_{D}=\sqrt{ε_{S}ε₀K_{B}T/e²n} and εₛ is the relative permittivity of the semiconductor, ε₀ the vacuum permittivity, k_{B} Boltzmann constant, T temperature, e elementary charge, and n charge carrier density.

Also disclosed herein is a method of making an electrode structure at sub-one hundred-nanometer (<100 nm) length scale. The method comprises forming a nanostructured template on a substrate, depositing a first metal on the template, and removing excess metal from the areas of the template desired to be metal-free. The nanostructured template can be an oxidized conductor patterned into a grating. The grating can have lines and grooves, where the width of the groove defines a spacing between the lines. The first metal can be deposited onto the top of the lines or into the grooves of the grating. The excess metal generated during deposition of the first metal is preferably removed from the bottom of the grooves if the first metal is deposited onto the top of the lines, or removed from the top of the lines if the first metal is deposited into the grooves.

The method can also include depositing a second metal. The second metal is preferably different from the first metal, e.g., different conducting composition. Alternatively, instead of depositing the first metal onto the top of the lines and the second metal into the grooves, the first metal can be deposited onto the top and one side of the lines, and the second metal can be deposited, onto the top and the opposing side of the lines. The excess metal is then removed from the top of the lines and the bottom of the grooves, for example, by ion milling. The method can further include removing the nanostructured template to produce a desired interdigitated electrode structure and adding the active material. By adding the active semiconducting material last, the active semiconducting material is not compromised by the use of high temperature and organic solvents during the production of the electrode structure. Preferably, a high-resolution lithography is used to produce electrode pitches (grooves and lines) of ˜100 nm or less and self-assembly is used to properly orient the active material within the produced grooves.

The disclosed method also includes using an electrode structure in a semiconducting device, preferably a transistor (e.g., FET) or a photovoltaic device (PV). The method includes the steps of electrically coupling the electrode structure to a semiconducting material of n- and/or p-type, thereby forming a semiconductor device. The electrode structure is operable to contain the semiconductor material. The electrode structure has a grating, i.e., a plurality of lines and grooves, and the semiconductor material is confined between lines of the grating. Preferably, the electrode structure has at least two conductors made from conducting materials of different composition. One of the conductors can make an electrical contact with the n-type semiconducting material and the other one of the conductors can make an electrical contact with the p-type semiconducting material.

The objectives, features and advantages of the disclosed invention will be apparent from the following detailed description, which is to be read in conjunction with the accompanying drawings. The scope of the invention will be pointed out in the claims. The following drawings, taken in conjunction with the subsequent description, are presented to enable one of ordinary skill in the art to make and use the invention and to incorporate it in the context of particular applications.

### BRIEF DESCRIPTION OF THE DRAWINGS

FIG. 1 is a schematic illustration of a conventional planar thin film geometry with the source/drain electrodes separated by a channel buried under a film of organic semiconductor.

FIG. 2 is a schematic illustration of a conventional device architecture with a vertical transistor channel.

FIG. 3 is a schematic illustration showing various geometries from the prior art that can reduce device footprint including planar channel, planar interdigitated, vertical channel, and vertical interdigitated geometries.

FIG. 4A is a schematic illustration showing P3HT stacking in transistors and contact placement, where the charge flow is across the planes of edge-on stacked P3HT.

FIG. 4B is a schematic illustration showing P3HT stacking in solar (PV) cells and contact placement, where the charge flow is along the planes of edge-on stacked P3HT.

FIG. 5 is a schematic illustration showing P3HT stacking having a plurality of interdigitated electrodes that help to orient the polymer.

FIG. 6A is a schematic illustration of an exemplary embodiment showing the electrode structure where the top electrode is positioned on the top of the grating of insulating columns.

FIG. 6B is a schematic illustration of an exemplary embodiment showing the electrode structure where the two interdigitated electrical contacts are placed on the substrate.

FIG. 6C is a schematic illustration of an exemplary embodiment showing the electrode structure where the two interdigitated electrical contacts on the substrate form thick columns allowing for horizontal charge collection.

FIG. 7 is a schematic illustration showing a vertical double gate low electronic mobility device architecture having thickness (d) that is about twice the charge screening length (L_{D}) of the semiconducting material (SC).

FIG. 8 is an exemplary process (1-4) for forming interdigitated electrical contacts on top and bottom of the substrate patterned in a grating.

FIG. 9A-9J is an illustration of an exemplary process for forming interdigitated electrical contacts prepared on the sides of the template grating.

FIG. 10A shows the setup of FIG. 5 having sub-hundred nanometer spacing and sub-hundred nanometer width electrodes.

FIG. 10B shows the setup of FIG. 10A with contacts on the top of pillars and the bottom of spaces between pillars, with the polymer blend in the spaces between the pillars.

FIG. 11A shows six images having the variation of the spacing between pillars in a patterned substrate and the stacking/orientation of the polymer(s).

FIG. 11B is an image showing the relationship between the stacking/orientation of the polymer(s) and the confinement width.

FIG. 11C is a plot showing the dependence of face-on vs. edge-on stacking (peak/total) on gap width (nm).

FIG. 12A shows five images showing the alignment of polymer stacking parallel to the axis of the interdigitated trenches.

FIG. 12B is a plot that shows polymer stacking alignment parallel to the axis of the interdigitated trenches for three different confinement gap widths (40 nm, 80 nm, and 160 nm). The inset summarizes the correlation between the confinement gap width and the alignment.

FIG. 13 shows 4 images of SEM cross sections and scattered grazing incidence X-ray diffraction (GIXRD) intensity for-planar and grating geometry templates coated with semiconducting polymer:fullerene (P3HT:PCBM) blend.

FIG. 14 is an image (200 nm) showing a vertical channel. organic FET constructed on an etched Si grating template.

FIG. 15 is an image (200 nm) showing the vertical channel organic FET of FIG. 8 with the tapered sidewalls of the etched structures that prevents metal deposition on vertical surfaces.

FIG. 16 is an image (200 nm) showing an organic semiconductor poly-3-hexylthiophene (P3HT) used as the active material.

FIG. 17A is a two-dimensional plot of scattered x-ray intensity obtained by grazing-incidence x-ray diffraction (GIXRD) from P3HT films formed on planar substrates. (Inset shows that the crystalline domains pack with lamellar ordering out of the film plane and π-π stacking in the substrate plane known as edge-on orientation).

FIG. 17B is a two-dimensional plot of scattered x-ray intensity obtained by grazing-incidence x-ray diffraction (GIXRD) from P3HT films confined within nanostructured gratings.

FIG. 17C is a plot that illustrates the orientation distribution along the (100) peak for vertical and planar electrode geometries.

FIG. 18 is a plot of field-effect transistor output characteristics for vertical channel interdigitated polymer semiconductor device (P3HT FET) at V_{G} of 0.2 V, 0.0 V, −0.2 V, −0.4 V, and −0.6 V with current per unit area >30 mA/cm² at V_{DS} =1 V normalized to L=370 nm, W/L=1.56×10⁶ and effective tₒₓ=17 nm.

FIG. 19A is a semi-log plot of field-effect transistor transfer characteristics for a vertical channel interdigitated polymer semiconductor device with V_{DS} of −1.0 V or −0.1 V. Linear fit provides measurement of sub-threshold slope (S) parameter.

FIG. 19B is a linear plot of field-effect transistor transfer characteristics for vertical channel interdigitated polymer semiconductor device with. V_{DS} of −0.1 V. Linear fit provides measure of the device transconductance, which is proportional to the semiconductor charge carrier mobility.

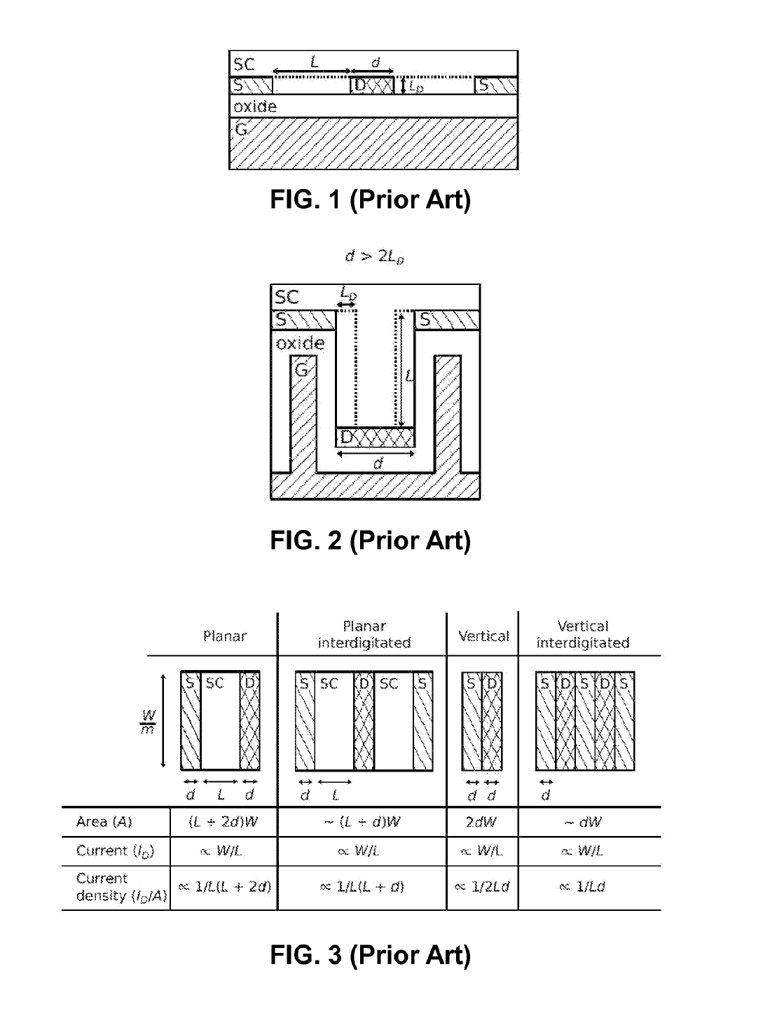

### DETAILED DESCRIPTION

Low electronic mobility semiconductor devices having interdigitated electrical contacts at a sub-one hundred-nanometer (<100 nm) length scale and the methods of manufacturing such devices without compromising the semiconducting material(s) are described. The low electronic mobility semiconductor devices generally have one or more electrodes preferably made from different materials patterned at a sub-one hundred-nanometer (<100 nm) length scale.

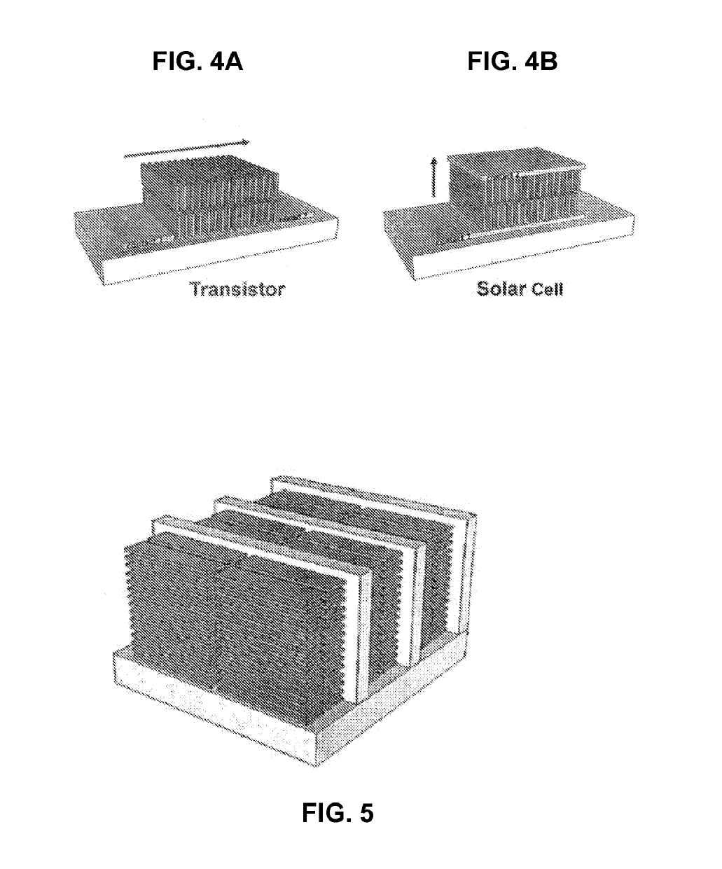

The architecture of the low electronic mobility semiconductor devices is dependent on its utility, such as whether the device is used as a photovoltaic device (PV) (see e.g., FIG. 4B) or as a transistor (e.g., FET) (see e.g., FIG. 4A). In a preferred embodiment, the semiconducting material is a blend of semi-crystalline organic polymers: P3HT (or poly(3-hexylthiophene)) and PCBM (or [6,6]-phenyl C₆₁-butyric acid methylester). The two polymers tend to segregate when mixed into different domains, where P3HT is a donor and PCBM is an acceptor. The P3HT tend to form lamellar with n-it stacking, which leads to charge mobility anisotropy or a different mobility depending on the direction of motion of the charge carriers as a result of the edge-on stacking. This anisotropy can be large, i.e., as high as 500X difference in hole mobility in P3HT depending on whether the holes. are moving along the chain direction (higher mobility) or tranverse to it (lower mobility). The direction of charge flow depends on the placement of the contacts. As illustrated in FIG. 4A, the contact placement for a transistor results in charge flow across the planes of edge-on stacked P3HT, while the contact placement for a PV (“solar”) cell, as illustrated in FIG. 4B results in charge flow along the planes. An electrode structure can be used to constrict the area in which a polymer is free to rearrange during solidification, offering an opportunity to orient the polymer chains. Thus, in the disclosed. electrode structures, the interdigitated electrodes are used to orient the polymer to occupy a small volume while covering a large area as shown in FIG. 5.

For the PV applications, the electrode structure is preferably designed to match charge carrier diffusion lengths. In one embodiment, an electrode structure generally has (1) a bottom electrode; (2) a top electrode, and (3) an insulating column operable to insulate the bottom electrode from the top electrode. The top electrode is positioned on the top surface of the insulating column, whereas the bottom electrode is. positioned on the substrate supporting the insulating column: The bottom electrode generally includes a continuous conducting layer positioned On the substrate that can extend under the insulating column. The insulating column can be positioned to be in contact with the substrate, while the bottom electrode does not extend between the insulating column and the substrate. The semiconducting material can be deposited between the insulating columns, preferably after the placement of the top and the bottom electrodes, which allows for top illumination. This eliminates the need for a transparent electrode and allows for a three-terminal geometry with tunable gate voltage. Alternatively, the two interdigitated electrodes can be placed on the substrate and the semiconducting material is layered on top of the electrodes. Of particular application to solar designs is an interdigitated electrode configuration with active material in the grooves that allows for top illumination. This eliminates the need for a transparent electrode and allows tuning of the gate voltage with this structure. The depth of either or both electrodes is preferably less than or equal to about 100 nanometers. The top electrode is preferably made from a conductor having a high work-function, such as platinum, gold, gold-palladium alloy, indium tin oxide, or poly(3,4-ethylenedioxythiophene):poly(styrenesulfonate) (PEDOT:PSS). The bottom electrode is preferably made from a conductor having a low work-function, such as aluminum, titanium, titanium oxide, or zinc oxide. The semiconducting material is preferably a polymer blend of P3HT/PCBM, although other semiconducting material can also be -used, such as polymer/polymer or nanoparticle blends. The insulating material is preferably made from plastic, e.g., polyethylene terephthalate (PET) or glass, e.g., silica, quartz, or fused silica. The substrate is preferably silicon (Si), although other substances such as aluminum, glass, quartz, fused. silica, polyethylene terephthalate (PET), can also be used.

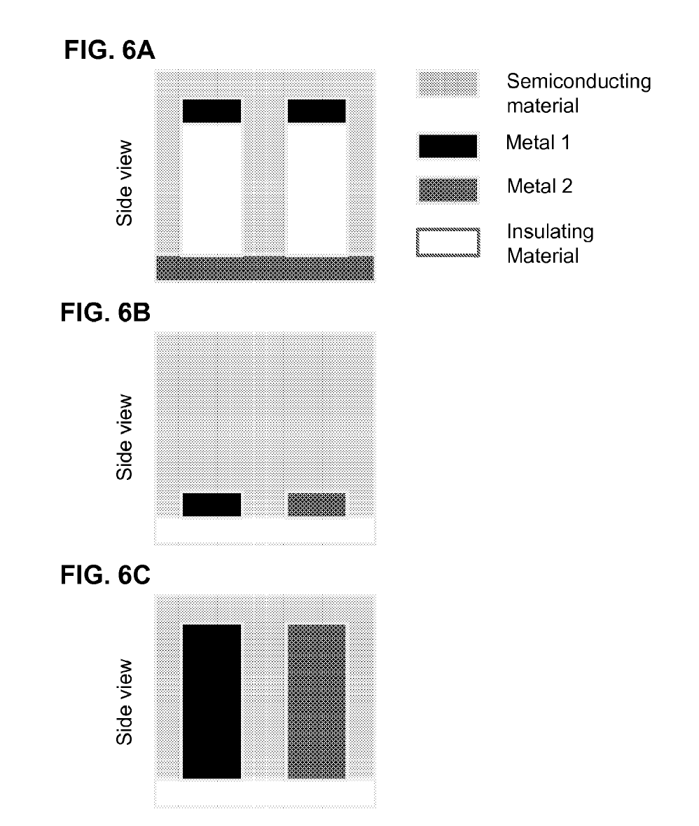

An exemplary embodiment is illustrated in FIG. 6A. where the top electrode (Metal 1) is positioned on top of the grating of insulating columns. The bottom electrode (Metal 2) is positioned on the substrate (not shown) at the bottom of the space or groove between insulating columns. The bottom electrode may be an exposed portion of an electrically conducting substrate (shown as Metal 2) or may be a deposited metal. Another exemplary embodiment is illustrated in FIG. 6B, where two interdigitated electrical contacts (or electrodes) are placed on an insulating substrate. In this configuration, the semiconducting material is deposited after both electrode materials have been deposited and patterned.

In another embodiment, an electrode structure has two (first and second) electrodes coplanar to each other that are supported on a common substrate. Preferably, the two interdigitated electrodes are placed on the substrate with the direction of the horizontal photogenerated charge collection orthogonal to the direction of the vertical light absorption. This provides for formation of thick active semiconducting layers for light absorption while maintaining short charge collection lengths: The electrodes can be made from different conducting materials and can be separated in the plane of the substrate by a predetermined linear distance. The electrodes are preferably made from one high work-function and one low work-function conducting material. The semiconducting material is preferably a polymer blend of P3HT/PCBM, although other semiconducting material can be used such as polymer/polymer or nanoparticle blends. The insulating material is preferably made from plastic or glass. The spacing between electrodes is set forth to depend on a characteristic charge carrier persistence length of the semiconducting material. Preferably, the depth of either or both electrodes is greater than about 100 nanometers. An exemplary embodiment of the disclosed electrode structure is shown in FIG. 6C, where the two interdigitated electrical contacts form tall columns on the substrate allowing for horizontal charge collection. In this configuration the active material may be deposited after both electrode materials have been deposited and patterned.

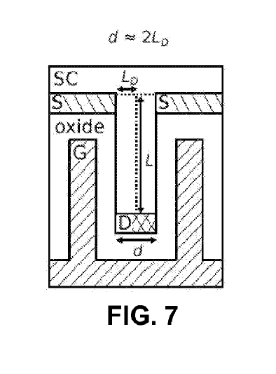

For the transistor applications, the electrode structure is preferably designed to reduce the device footprint, yet provide an enhanced gate coupling strength by adopting a vertical double gate architecture that effectively eliminates the source of the drain leakage currents due to the presence of the inactive semiconductor material. As illustrated in FIG. 7, the electrode structure has two (S and D) electrodes coplanar to each other supported on a common substrate (e.g., G and an oxidized conductor layer) and separated by channel length. (L) and a channel width (W) (not shown). The semiconducting material (SC), preferably a conductive polymer blend (PCBM/P3HT) or inorganic nanocrystals, is deposited in the grooves. The current output magnitude (I_{D}) is controlled by scaling the ratio (W/L) of the channel width (W) to length (L). Thus, the channel length and width are not particularly limited. However, increasing channel width (W) increases device area, which is undesirable; whereas reducing channel length (L) is limited by the gate oxide thickness (tₒₓ) and the resolution of the patterning method used to fabricate electrodes. Therefore, the disclosed electrode structure achieves the desired properties by having vertically interdigitated electrodes with depth or thickness (d) that is smaller or equal to twice the charge screening length (L_{D}) of the semiconducting material, which can be expressed as,

d≦2L_{D} (1).

where L_{D}=\sqrt{ε_{S}ε₀K_{B}T/e²n} and εₛ is the relative permittivity of the semiconductor, ε₀ the vacuum permittivity, k_{B} Boltzmann constant, T temperature, e elementary charge, and n charge carrier density.

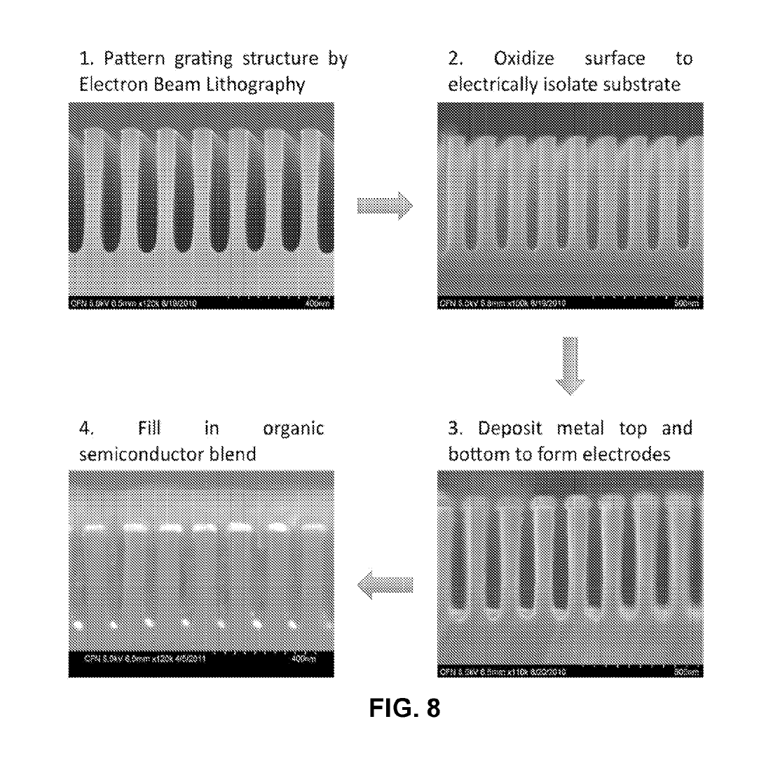

Also disclosed herein is a method of making an electrode structure. The method comprises forming a nanostructured template on a substrate, depositing a first metal on the template, and removing excess metal from areas of the template desired to be metal-free as illustrated in FIG. 8. Preferably, the active semiconducting material is added last to avoid high temperature and harmful organic solvents that may damage the fragile semiconducting material. (See FIG. 8:4. Fill in organic semiconductor blend). As shown in FIG. 8, a nanostructured template is first formed by any technique known in the art. Preferably, a high-resolution electron beam lithography is used to produce electrode pitches (grooves and lines) of ˜100 nm or less. (See FIG. 8: 1. Pattern grating structure by Electron beam lithography). The template has grating formed in an electrically conductive substrate. The grating can have lines and grooves, where the width of the groove defines a spacing between the lines. Next, the grating is oxidized to form an insulating layer on its surface. (See FIG. 8: 2. Oxidize surface to electrically isolate substrate). The insulator electrically isolates the surface from the conducting substrate. Then, the metal is deposited onto the top of the lines or into the grooves of the grating to form top and bottom contacts. (See FIG. 8: 3. Deposit metal top and bottom to form electrodes). This may be done singly for top and bottom contacts made from the same material; or serially to deposit different metallic material as the top and the bottom electrodes. After the formation of the electrodes, the template is filled with active semiconducting material. (See FIG. 8: 4. Fill in organic semiconductor blend). This active material may be organic, such as conductive polymer blends, or inorganic, such as nanocrystals. The method can further include removing the nanostructured template to produce the final electrode structure.

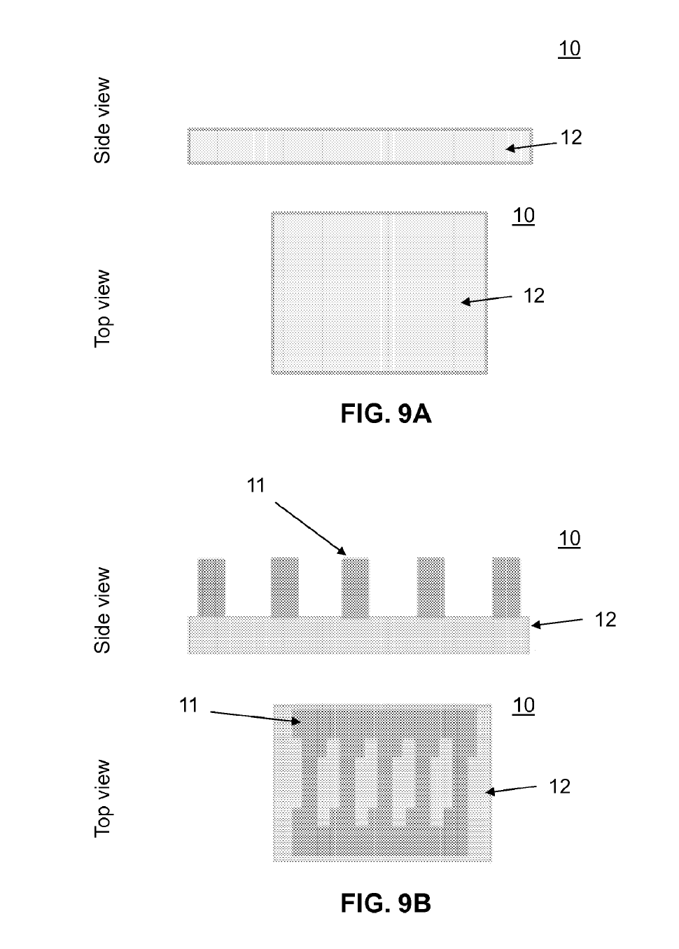

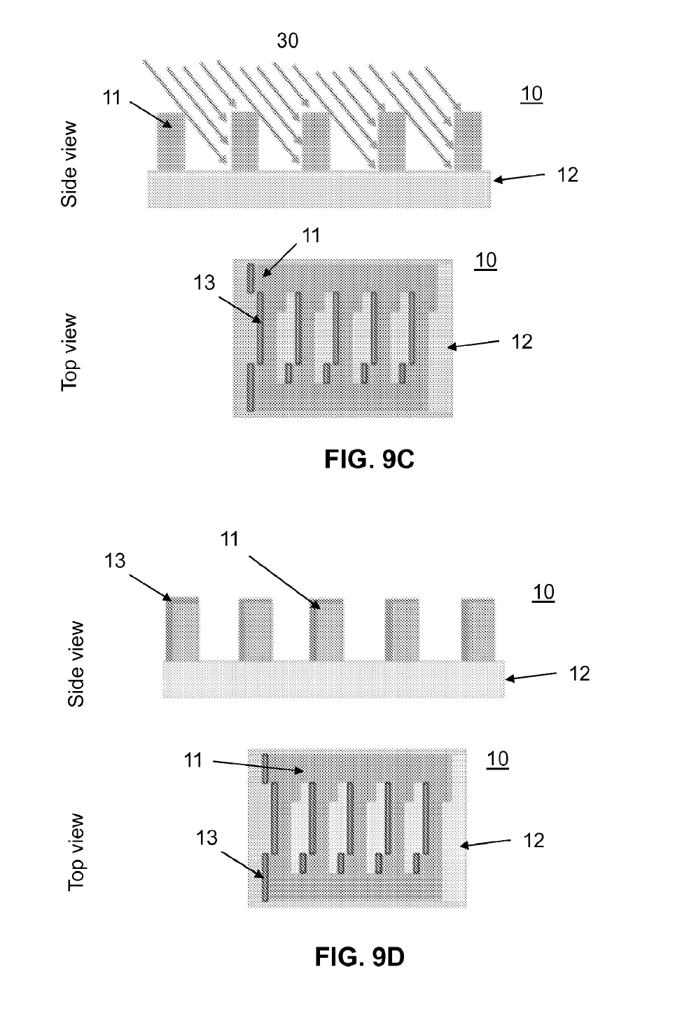

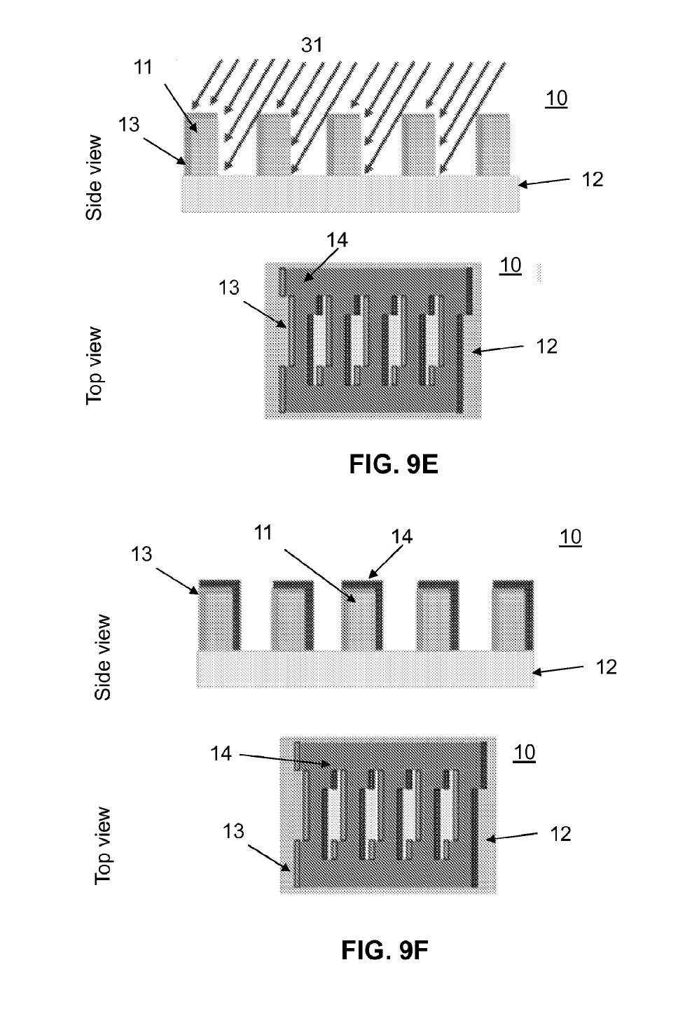

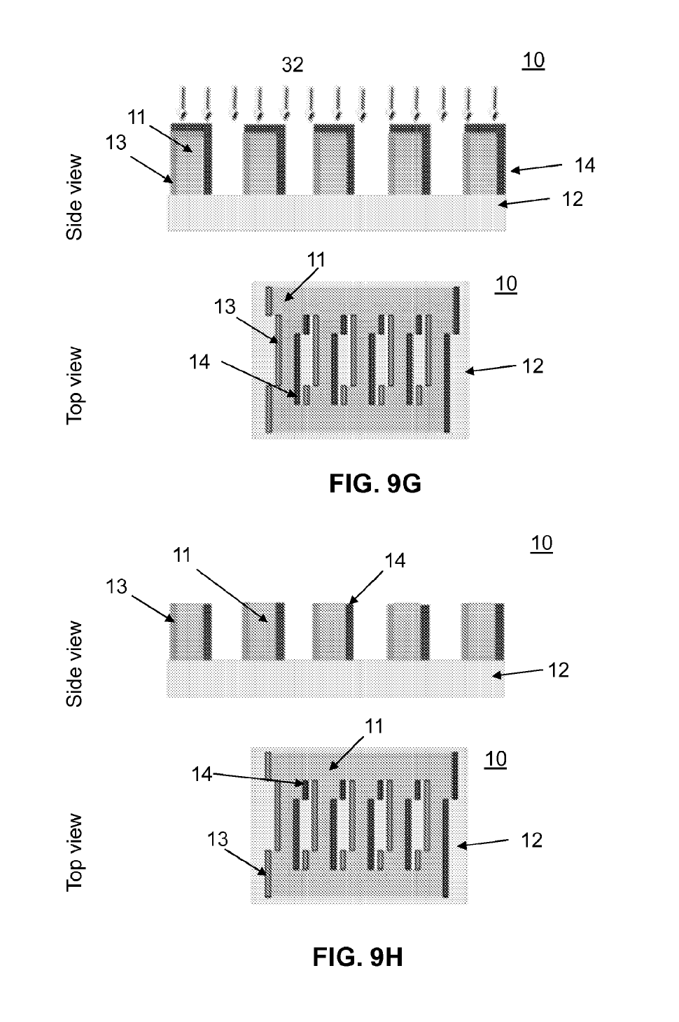

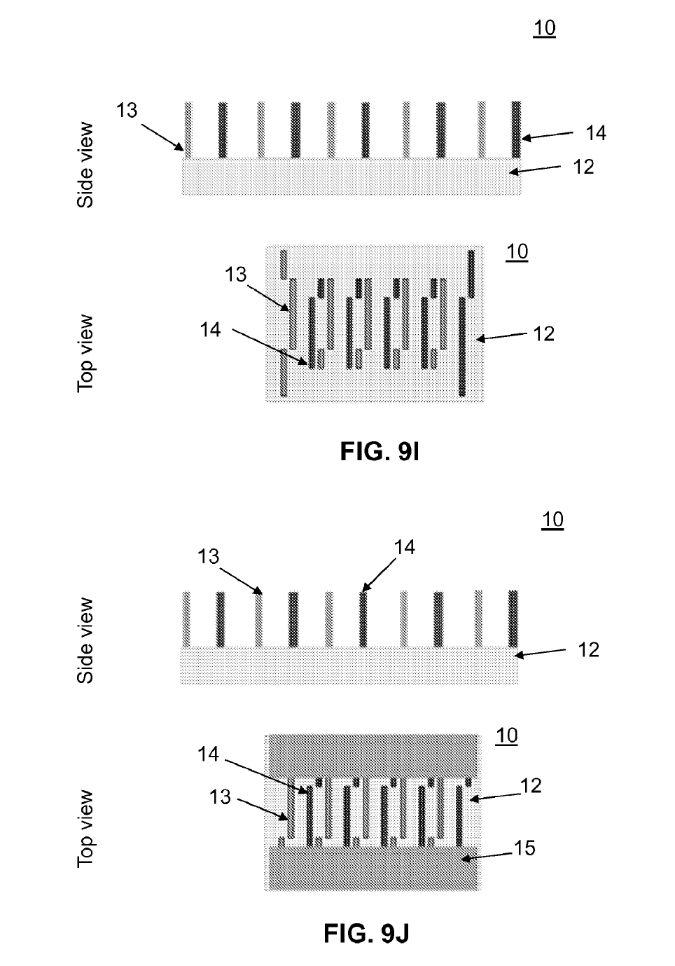

Alternatively, the method can be modified to produce vertical contacts as illustrated in FIGS. 9A-9J. Beginning with a flat substrate 12 illustrated in FIG. 9A, an electrode structure 11 can be prepared using various methods known in the art, preferably by using negative resist and lithography. The electrode pattern 11 can be seen in FIG. 9B. The first metal 13 is then deposited at an angle 30 to the electrode pattern 11 formed by the negative resist (see FIG. 9C) to produce an electrode pattern 11 with metal 13 shown in FIG. 9D. The second metal 14 is then deposited at a complementary angle 31 onto the metallized negative resist structure (11 & 13) as illustrated in FIG. 9E. Top and side views of the resulting structure are shown in FIG. 3F. Ion milling 32, or other directed etching process, is used to remove excess metal 13 & 14 from the top of the negative resist structure 11 as shown in FIG. 9G. This results in the contact structure illustrated in FIG. 9H. The resist 11 is then stripped, leaving in place thick contacts of alternating metal 13 and 14 spaced apart by an amount depending on the original negative resist structure 11 as shown in FIG. 91. Contact pads 15 may then be deposited using a shadow mask as shown in FIG. 9J. The final structure is then ready for deposition of the active organic or nanocrystalline material.

Also disclosed herein is a method of using an electrode structure in a semiconducting device, preferably a transistor (e.g., FET) or a photovoltaic device (PV). The method includes electrically coupling the electrode structure to a semiconductor material of n- and/or p-type, to form a semiconductor device. The electrode structure is operable to contain the semiconductor material. The electrode structure has a grating in which the semiconductor material is confined between lines of the grating. Preferably, the electrode structure has at least two conductors made from conducting materials of different composition. One of the conductors can make an electrical contact with the n-type semiconducting material and the other one of the conductors can make an electrical contact with the p-type semiconducting material.

### EXAMPLES

### Example 1

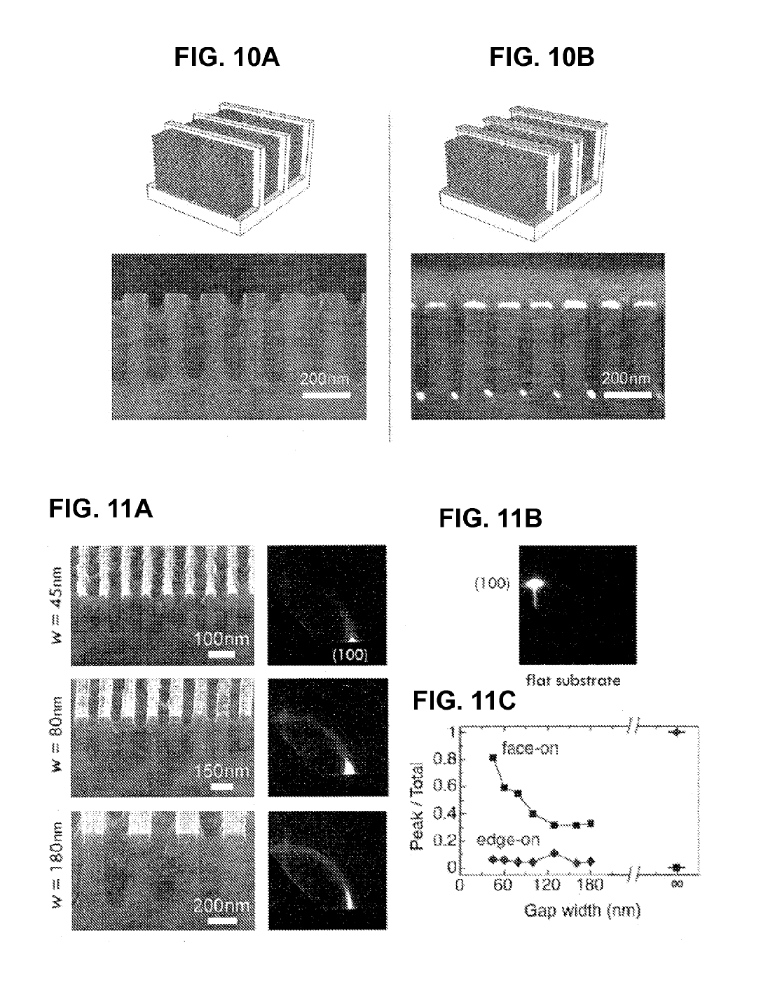

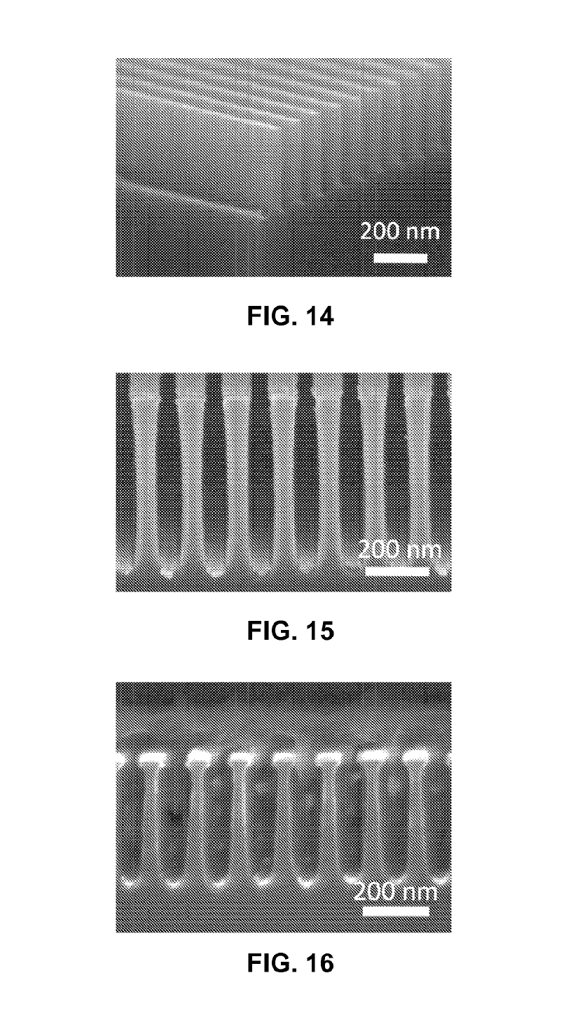

A vertical channel organic low mobility system was constructed on an etched silicon (Si) grating template having lithographically defined trenches of constant width and height. (See FIGS. 10A and 14) The height defines the channel. length (L) in the grating. Thermally grown silicon oxide together with a thin coating of aluminum oxide were used to form the gate dielectric layers. The doped Si substrate serves as gate electrode. A gold/palladium. (Au/Pd) alloy was deposited as a film. perpendicular to the plane of the substrate to form source and drain electrodes. FIG. 10B illustrates the electrode structure constructed having contacts on the top of pillars. and the bottom of spaces between pillars, with the polymer blend (PCBM/P3HT) in the ,spaces between the pillars.

### Example 2

As shown in FIG. 11A, the smaller the confinement width, i.e., spacing between pillars in a patterned substrate, the larger the fraction of the polymer that has oriented its lamellar stacking direction in the horizontal direction implying a larger face-on population. The microscope images of three different grating templates with the confinement width of 45 nm, 80 nm and 180 nm and its lamellar stacking direction are shown in FIG. 11A. FIG. 11B shows the relationship between the stacking/ orientation of the polymer(s) and the confinement width, and FIG. 11C shows the dependence of face-on vs. edge-on stacking (peak/total) on gap width (nm)

### Example 3

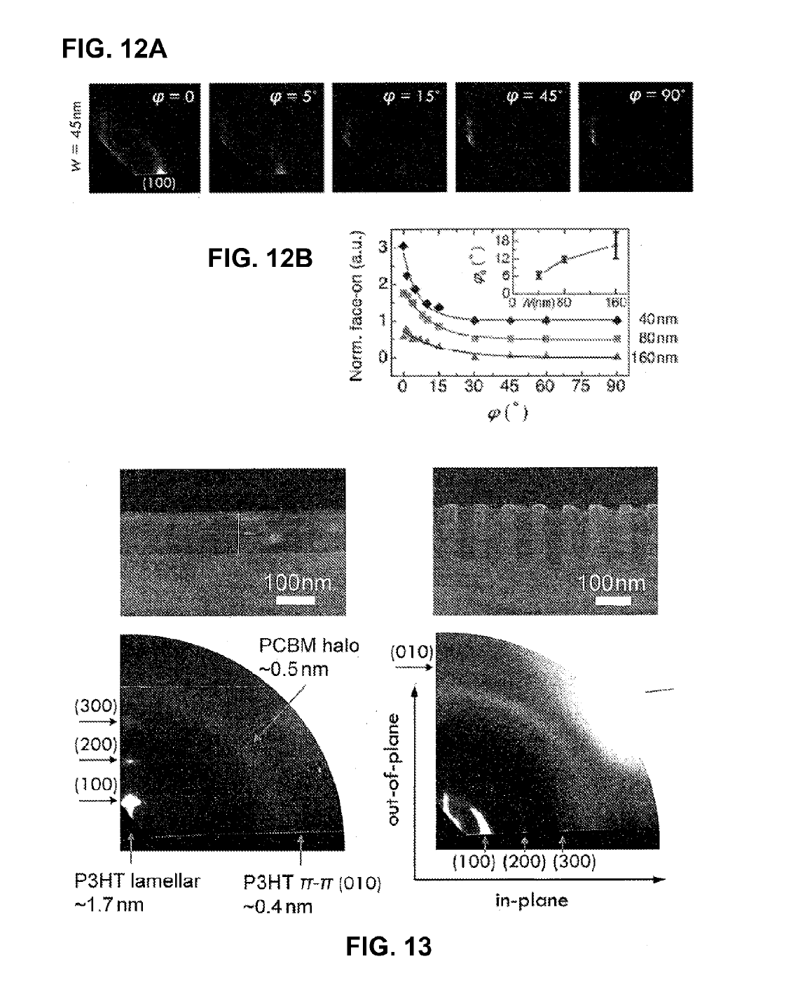

The axial alignment of lamellar stacking also depends on the confinement width as illustrated in FIG. 12A. By choosing the width of the template (pillars) and the spacing between them, the orientation of semi-crystalline polymers can be controlled. Near-complete reorientation of the polymer stacking direction was possible with small confinement widths as shown in FIG. 12B. To reduce the template volume fraction, and thereby to increase the amount of active material, the spacing between template pillars/walls, i.e., the groove width, was increased within limits set by the need to reorient the polymer chain stacking. Large area coverage of nanostructured films was appropriate for the desired devices. Self-assembly based techniques may be used to generate the template and/or the oriented polymer structures.

### Example 4

FIG. 13 shows the differences in semiconducting polymer-fullerene stacking between flat (planar) and patterned (grated) films. The flat film shown on the left side of FIG. 13 exhibits a predominantly edge-on configuration, while for the patterned substrate shown on the right side of FIG. 13, the stacking is predominantly face-on.

### Example 5

FIG. 14 illustrates a vertical channel organic FET constructed on an etched Si grating template having lithographically defined trenches 40 nm wide and approximately 370 nm in height. This height defines the channel length in the grating organic FET. Thermally grown silicon oxide (15 nm) together with a thin coating of aluminum oxide (4 nm) form the gate dielectric layer. The doped Si substrate serves as gate electrode. An AuPd film (20 nm) is deposited perpendicular to the plane of the substrate to form source and drain electrodes. As shown in FIG. 15, tapered sidewalls of the etched structures prevents metal deposition on vertical surfaces.

### Example 6

The organic semiconductor poly-3-hexylthiophene (P3HT) is used as the active material (see FIG. 16). When the semiconductor is fully depleted (sub-threshold regime), the Debye length (L_{D}>60 nm for n<10¹⁵ cm⁻³) was larger than the confining channel width (40 nm). However, in the fully on-state, increased n shrinked L_{D} to less than a few nanometers. Therefore, the active region had all the semiconductor material during part of the range of operation.

### Example 7

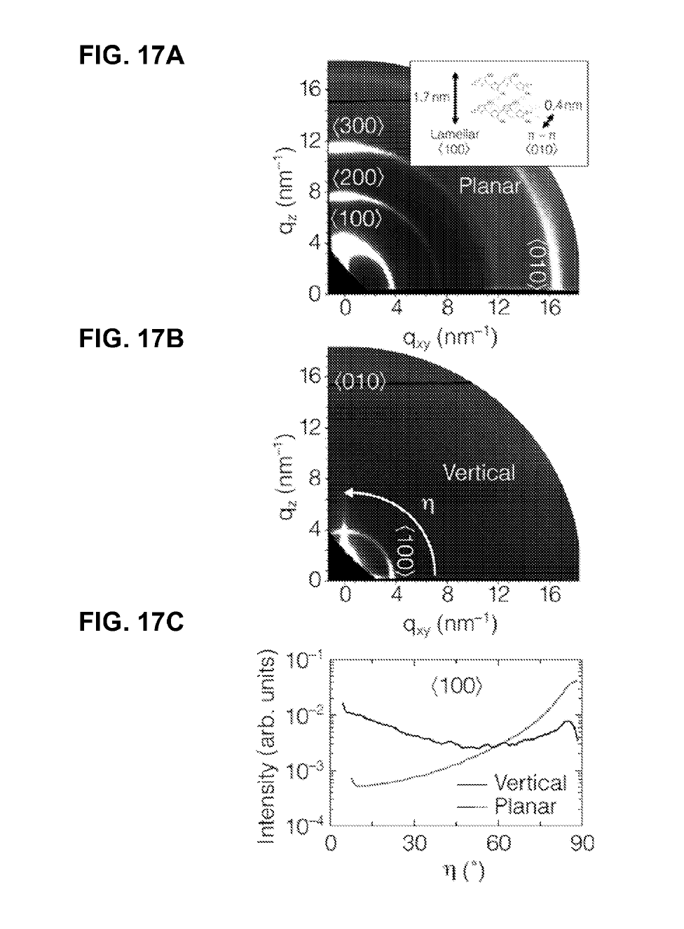

In P3HT films, polymer chains self-organized into semi-crystalline domains due to inter-molecular π-π stacking and orthogonal lamellar ordering due to the side chains. Typically, the crystalline domains pack with lamellar ordering out of the film plane and π-π stacking in the substrate plane (known as edge-on orientation) as shown schematically in FIG. 17A inset. The charge carrier mobility of P3HT was highly anisotropic, with values varying >100 times depending on the current flow direction relative to polymer chain stacking orientation.

Comparison of two-dimensional plots of scattered x-ray intensity illustrated in FIGS. 17A and 17B obtained by grazing-incidence x-ray diffraction (GIXRD) from P3HT films formed on planar substrates and confined within nanostructured gratings revealed that a significant fraction of polymer chains have reoriented by 90° from the edge-on configuration upon confinement. The orientation distribution along the (100) peak, estimated by integrating along arcs at constant radius of the q-vector showed a crossover between the two molecular orientations (see FIG. 17C). The differences in relative intensity at η=90° (out-of-plane scattering vector) between planar and confined P3HT films showed that a share of the polymer has rotated the lamellar ordering direction perpendicular to the channels of our organic FET devices. Consistent with a significant P3HT molecular population reorienting within the vertical channel relative to its orientation in a planar film, it is believed that similar P3HT field-effect mobilities should be observed in both vertical and planar devices.

### Example 8

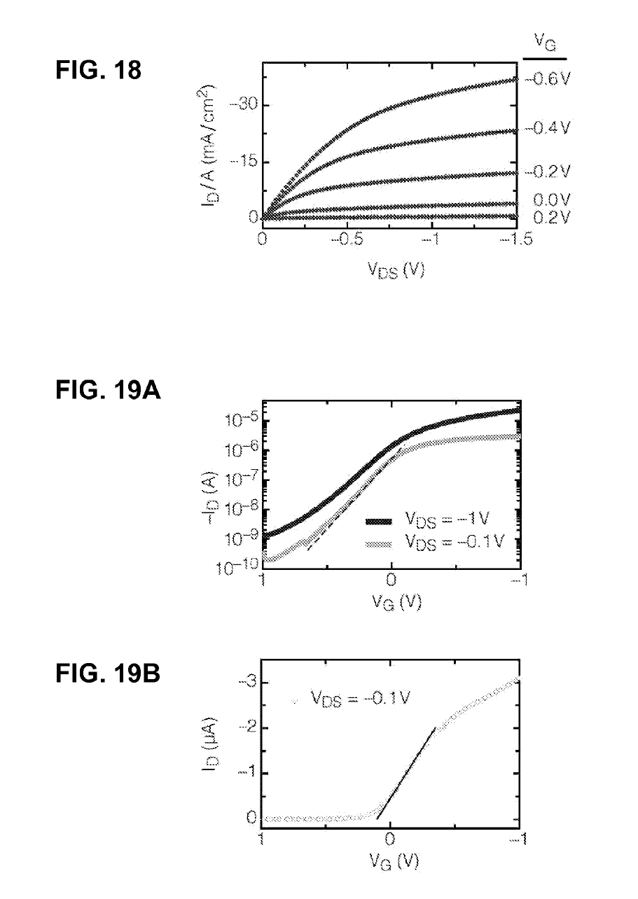

This example illustrates the FET electrical performance. FIG. 18 shows normalized current output characteristics for vertical channel P3HT FET normalized to L=370 nm, W/L=1.56×10⁶ and effective tₒₓ=17 nm. FIGS. 19A and 19B show transfer characteristics for the vertical channel FET with (A) semi-log and (B) linear plot.

It will be appreciated by persons skilled in the art that the present invention is not limited to what has been particularly shown and described. Rather, the scope of the present invention is defined by the claims which follow. It should further be understood that the above description is only representative of illustrative examples of embodiments. The description has not attempted to exhaustively enumerate all possible variations. The alternate embodiments may not have been presented for a specific portion of the invention, and may result from a different combination of described portions, or that other =described alternate embodiments may be available for a portion, is not to be considered a disclaimer of those alternate embodiments. It will be appreciated that many of those =described embodiments are within the literal scope of the following claims, and others are equivalent. Furthermore, all references, publications, U.S. Patents, and U.S. Patent Application Publications cited throughout this specification are hereby incorporated by reference as if fully set forth in this specification.

What is claimed is:

1. An electrode structure, comprising:
a bottom electrode;
a top electrode; and
an insulating column operable to insulate the bottom electrode from the top electrode, wherein the insulating column has a height and a width and the height of the insulating column is equal to or less than 200 nm and the width is equal to or less than 100 nm;
wherein the top electrode is positioned on a top surface of the insulating column, the insulating column is supported by a substrate, the bottom electrode is positioned on top of the substrate supporting the insulating column, and the bottom electrode does not extend between the insulating column and the substrate.

2. The electrode structure of claim 1, wherein the bottom electrode comprises:
aluminum, titanium, titanium oxide, zinc oxide or a combination thereof.

3. (canceled)

4. (canceled)

5. (canceled)

6. (canceled)

7. (canceled)

8. The electrode structure of claim 1, wherein a length between adjacent insulating columns is equal to or less than 100 nm and matches a charge carrier diffusion length.

9. (canceled)

10. (canceled)

11. (canceled)

12. (canceled)

13. (canceled)

14. An electrode structure, comprising:
a first electrode on a first plane, having a first thickness, a first width, and a first length; and
a second electrode on a second plane, having a second thickness, a second width, and a second length;
wherein the first and second planes are parallel and on a common substrate, wherein the first plane is on a top surface of the substrate, the second plane is below the top surface of the substrate and the first and second planes are separated by a linear distance;
wherein the first width and the second width are equal to or less than 100 nanometers.

15. The electrode structure of claim 14, wherein the first and second electrodes comprise distinct conducting materials.

16. The electrode structure of claim 15, wherein the conducting material is selected from the group consisting of aluminum, titanium, platinum, gold, gold-palladium alloy, titanium oxide, zinc oxide, indium tin oxide, and poly(3,4-ethylenedioxythiophene):poly(styrenesulfonate) (PEDOT:PSS).

17. The electrode structure of claim 14, wherein the first width and the second width are approximately equal to the predetermined linear distance between the first and second electrodes.

18. The electrode structure of claim 14, further comprising:
a third electrode on a third plane, having a third thickness, a third width, and a third length; and
a fourth electrode on a fourth plane, having a fourth thickness, a fourth width, and a fourth length;
wherein the third and fourth planes are parallel, wherein the third plane is on the top surface of the substrate, the fourth plane is below the top surface of the substrate and the third and fourth planes are separated by the linear distance;
wherein the third width and the fourth width are equal to or less than 100 nanometers; and a semiconducting material between the second and third electrodes.

19. (canceled)

20. (canceled)

21. (canceled)

22. (canceled)

23. (canceled)

24. The electrode structure of claim 18, wherein the semiconducting material comprises inorganic nanocrystals.

25. The electrode structure of claim 18, wherein the first width and the second width are of the order of a characteristic charge carrier persistence length of the semiconducting material.

26. A semiconducting device, comprising:
a substrate patterned into a grating;
a bottom electrode on a first plane and positioned in a groove of the substrate;
a top electrode on a second plane parallel to the first plane positioned on a top surface of the substrate; and
a semiconducting material disposed on top of the bottom electrode filling the groove and extending over the top electrode;
wherein the parallel planes of the top electrode and the bottom electrode are separated in the substrate by a channel length and the thickness of the top electrode and the bottom electrode is less than about 100 nanometers.

27. The semiconducting device of claim 26, wherein the bottom electrode has a thickness (d) that is smaller or equal to twice a charge screening length (LD) having formula
L_{D}=\sqrt{ε_{S}ε₀k_{B}T/e²n,}
where εₛ is the relative permittivity of the semiconducting material, ε₀ is the vacuum permittivity, k_{B} is the Boltzmann constant, T is temperature, e is the elementary charge, and n is the charge carrier density.

28. (canceled)

29. The semiconducting device of claim 26, wherein the substrate is coated by an oxidized conducting layer.

30. (canceled)

31. (canceled)

32. (canceled)

33. The semiconducting device of claim 26, wherein the top electrode and the bottom electrode comprise distinct conducting materials.

34. (canceled)

35. (canceled)

36. (canceled)

37. The semiconducting device of claim 26, wherein a thickness of the bottom electrode is about 40 nm and a charge screening length of the semiconducting material is greater than 60 nm in a fully depleted state.

38. A method of making an electrode structure, the method comprising:
forming a nanostructured template on a substrate;
depositing a first metal on the template; and
removing at least some of the deposited metal from the template
wherein the nanostructured template comprises an oxidized conductor patterned into a grating, the grating comprising lines and grooves, each line having a height and a top surface, a width and two opposing sides, and a length, and each groove having a width and a bottom, the width of the groove defining a spacing between the lines, and the width of the lines and grooves is equal to or less than 100 nm.

39. The method of claim 38, wherein:
depositing the first metal comprises depositing a metal onto the top surface of the lines of the grating; and
removing at least some of the deposited metal comprises removing metal from the bottom of the grooves.

40. The method of claim 38, wherein:
depositing the first metal comprises depositing a metal into the grooves; and
removing at least some of the deposited metal comprises removing metal from the top surface of the lines.

41. The method of claim 38, further comprising:
depositing a second metal.

42. The method of claim 41, wherein the second metal comprises a different conducting composition from the first metal.

43. The method of claim 42, wherein depositing the first metal comprises depositing a metal onto the top surface and a first side of the two opposing sides of the lines.

44. The method of claim 43, wherein depositing the second metal comprises depositing a metal onto the top surface and a second side opposing the first side of the lines.

45. The method of claim 38, wherein removing at least some of the deposited metal comprises removing metal from the top surface of the lines and the bottom of the grooves.

46. The method of claim 38, further comprising removing the nanostructured template.
